(19) United States
(12) Patent Application Publication
(10) Pub. No.: US 2019/0027908 A1
(43) Pub. Date: Jan. 24, 2019

(54) TUBULAR CONDUCTIVE BRAID AND WIRING MODULE WITH ELECTROMAGNETIC SHIELD

(71) Applicants: AutoNetworks Technologies, Ltd., Yokkaichi-shi, Mie (JP); Sumitomo Wiring Systems, Ltd., Yokkaichi-shi, Mie (JP); SUMITOMO ELECTRIC INDUSTRIES, LTD., Osaka-shi, Osaka (JP)

(72) Inventors: Tomoya Kawaguchi, Yokkaichi, Mie (JP); Masaharu Suetani, Yokkaichi, Mie (JP); Takeshi Shimizu, Yokkaichi, Mie (JP)

(21) Appl. No.: 15/753,667

(22) PCT Filed: Aug. 4, 2016
(86) PCT No.: PCT/JP2016/072958

§ 371 Date: Feb. 20, 2018

(30) Foreign Application Priority Data
Aug. 24, 2015 (JP) 2015-164722

(51) Int. Cl. H02G 3/04; H01B 7/17; H05K 9/00; H01R 13/648

(52) U.S. Cl. CPC H02G 3/04; H01B 7/17; H01R 2201/26; H05K 9/0098; H01R 13/648; H05K 9/0081

(57) ABSTRACT

An object of the present invention is to prevent, as much as possible, a braid from having inductance. A tubular conductive braid includes first conductive wires that describe a helix and second conductive wires that describe a helix in a direction opposite to the first conductive wires about a helix axis that is the same as a helix axis (X) of the first conductive wire, the first conductive wires and the second conductive wires being combined so as to form a tubular shape. The first conductive wires and the second conductive wires are electrically and mechanically connected at multiple locations on a line that extends along the helix axis.

### CROSS-REFERENCE TO RELATED APPLICATIONS

This application is the U.S. national stage of PCT/JP2016/072958 filed Aug. 4, 2016, which claims priority of Japanese Patent Application No. JP 2015-164722 filed Aug. 24, 2015.

### TECHNICAL FIELD

This invention relates to a tubular conductive braid in which conductive wires are combined into a tubular shape.

### BACKGROUND ART

JP 2013-73987A discloses a technique in which a tubular braid is formed using a large number of conductive strands, and this braid is used as a shield.

In a braid such as that disclosed in JP 2013-73987A, a large number of strands are combined so as to describe helixes in two helical directions and form a tubular shape.

For this reason, current generated in the strands by electromagnetic noise flows through the entirety of the tubular braid while branching at intersections with other strands.

However, as a braid degrades, oxide films or the like are formed on surfaces of the braid. Electrical resistance therefore rises at intersections between strands. When this happens, current generated in the strands flows along a helical path instead of branching to other strands. Accordingly, the current path for the escape of electromagnetic noise has inductance. If a braid is used as an electromagnetic shield, the shield performance decreases.

In view of this, an object of the present invention is to prevent, as much as possible, a braid from having inductance.

### SUMMARY

In order to solve the foregoing problem, a tubular conductive braid according to a first aspect includes: first conductive wires that describe a helix and second conductive wires that describe a helix in a direction opposite to the first conductive wires about a helix axis that is the same as a helix axis of the first conductive wires, the first conductive wires and the second conductive wires being combined so as to form a tubular shape, wherein the first conductive wires and the second conductive wires are electrically and mechanically connected at a plurality of locations on a line that extends along the helix axis.

A second aspect is the tubular conductive braid according to the first aspect, wherein the first conductive wires and the second conductive wires are electrically and mechanically connected at intersections therebetween.

A third aspect is the tubular conductive braid according to the second aspect, wherein a linear conductor is arranged along the line, and an electrical and mechanical connection portion of the first conductive wires and the second conductive wires is electrically and mechanically connected to the linear conductor.

A fourth aspect is the tubular conductive braid according to any one of the first to third aspects, wherein the first conductive wires and the second conductive wires are electrically and mechanically connected by soldering or welding.

A fifth aspect is the tubular conductive braid according to the second aspect, wherein the first conductive wires and the second conductive wires are electrically and mechanically connected via a linear conductor that is arranged extending along the line.

A sixth aspect is the tubular conductive braid according to the fifth aspect, wherein the first conductive wires and the second conductive wires are electrically and mechanically connected via the linear conductor by being soldered or welded to the linear conductor.

A seventh aspect is the tubular conductive braid according to any one of the first to sixth aspects, wherein the first conductive wires and the second conductive wires are electrically and mechanically connected in a portion arranged in a straight path, in a direction along the helix axis.

An eighth aspect is the tubular conductive braid according to any one of the first to seventh aspects, wherein the first conductive wires and the second conductive wires are electrically and mechanically connected in a portion excluding a portion arranged along a curved path, in a direction along the helix axis.

Also, a wiring module with electromagnetic shield according to a ninth aspect includes: a wiring member; and the tubular conductive braid according to any one of the first to eighth aspects, the tubular conductive braid surrounding the wiring member as an electromagnetic shield.

### Advantageous Effects of Invention

According to the first aspect, the first conductive wires and the second conductive wires are electrically and mechanically connected at multiple locations along a line that extends along the helix axis, and therefore current flowing along the first conductive wires is branched to the second conductive wires at a midpoint. Similarly, current flowing along the second conductive wires is also branched to the first conductive wires at a midpoint. In particular, because the first conductive wires and the second conductive wires are mechanically connected, the state of the electrical connection between the first conductive wires and the second conductive wires is also maintained in a favorable state. For this reason, current flowing along the first conductive wires and the second conductive wires is not likely to rotate many times around the helix axis, and as a result, it is possible to prevent, as much as possible, the tubular conductive braid from having inductance.

According to the second aspect, the first conductive wires and the second conductive wires can be easily electrically and mechanically connected at intersections therebetween.

According to the third aspect, current flowing along the first conductive wires and the second conductive wires also flows along the linear conductor that extends along the line. For this reason, it is possible to further reduce inductance.

According to the fourth aspect, the first conductive wires and the second conductive wires can be electrically and mechanically connected more reliably by soldering or welding.

According to the fifth aspect, current flows along the linear conductor, thus making it possible to further reduce inductance.

According to the sixth aspect, the first conductive wires and the second conductive wires can be electrically and mechanically connected more reliably by soldering or welding.

According to the seventh aspect, a portion of the tubular conductive braid that is arranged along a straight path can be easily maintained in a straight shape.

According to the eighth aspect, a portion of the tubular conductive braid that is to be arranged along a curved path can be curved easily.

According to the ninth aspect, a tubular conductive braid that is to serve as an electromagnetic shield is not likely to have inductance. For this reason, it is possible to allow current generated in the tubular conductive braid to escape more easily, and it is possible to obtain favorable shielding performance.

### BRIEF DESCRIPTION OF DRAWINGS

FIG. 1 is a schematic perspective view of a wiring module with electromagnetic shield according to a first embodiment.

FIG. 2 is a schematic side view of a tubular conductive braid.

FIG. 3 is an illustrative diagram showing an example of an operation of connecting first conductive wires and second conductive wires.

FIG. 4 is an illustrative diagram showing an example of an operation of connecting first conductive wires and second conductive wires.

FIG. 5 is an illustrative diagram showing an example of an operation of connecting first conductive wires and second conductive wires.

FIG. 6 is a schematic side view of a tubular conductive braid according to a first variation.

FIG. 7 is an illustrative diagram showing an example of an operation of connecting first conductive wires and second conductive wires.

FIG. 8 is a schematic side view of a tubular conductive braid according to a second embodiment.

FIG. 9 is an illustrative diagram showing an example of an operation of connecting first conductive wires, second conductive wires, and a linear conductor.

FIG. 10 is a schematic partial side view of a tubular conductive braid according to a third embodiment.

FIG. 11 is an illustrative diagram showing a tubular conductive braid and a wiring module with electromagnetic shield according to a second variation.

### DETAILED DESCRIPTION OF PREFERRED EMBODIMENTS

### First Embodiment

A tubular conductive braid and a wiring module with electromagnetic shield according to a first embodiment will be described below.

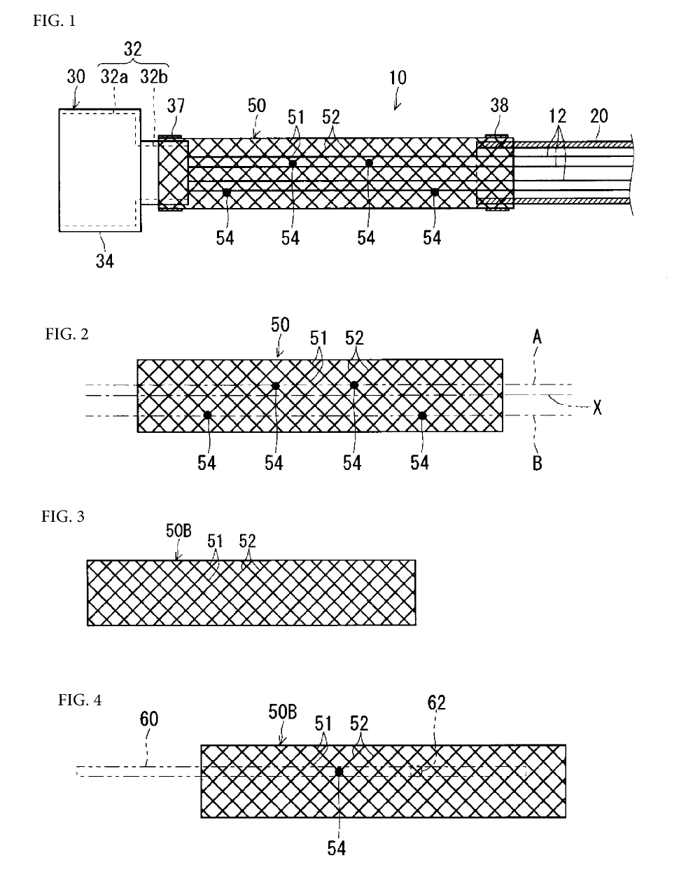

FIG. 1 is a schematic perspective view of a wiring module with electromagnetic shield 10, and FIG. 2 is a schematic side view of a tubular conductive braid 50.

The wiring module with electromagnetic shield 10 includes at least one sheathed electrical wire 12 as a wiring member, and also includes the tubular conductive braid 50 as an electromagnetic shield. Also, here, the wiring module with electromagnetic shield 10 includes a tubular member 20 and a connector 30. It is not essential in the first place that the wiring module with electromagnetic shield 10 includes the tubular member 20 and the connector 30.

Here, the wiring module with electromagnetic shield 10 includes multiple sheathed electrical wires 12, and the sheathed electrical wires 12 are bundled together into one group. The sheathed electrical wires 12 each include a core wire and a sheath that surrounds the core wire. The core wire is a wire member that is made of a metal such as copper, a copper alloy, aluminum, or an aluminum alloy. The core wire may be formed by twisting strands together, or may be constituted by a single wire. The sheath is an insulating member formed from a resin or the like, and is formed by extrusion coating or the like so as to cover the core wire. The sheath may be formed by films that sandwich the core wire, or may be constituted by a heat shrink tube that is heat-shrunk while covering the core wire. The sheathed electrical wire 12 is used as a power line for supplying electricity or a signal line for transmitting electrical signals. In either case, current flows along the sheathed electrical wires 12. In the following description, it is envisioned that the sheathed electrical wires 12 are power lines for supplying three-phase alternating current, and that three sheathed electrical wires 12 are bundled into one group. Note that it is not required that multiple sheathed electrical wires are bundled together, and the number of sheathed electrical wires that are provided may be one, two, or more.

The connector 30 includes a housing portion 32 and a conductive shell 34.

The housing portion 32 is a member that is formed from an insulating material such as a resin. This housing portion 32 includes a housing main body portion 32a whose outer circumferential surface has a cuboid outer circumferential surface shape, and a coupling portion 32b that is coupled to one end portion of the housing main body portion 32a (the end portion on the side to which the sheathed electrical wires 12 are connected). The coupling portion 32b is formed with a narrower shape (here, a cuboid shape) than the housing main body portion 32a.

Terminal portions that correspond to the sheathed electrical wires 12 are embedded in the housing portion 32. The terminal portions are respectively connected to the core wires of the sheathed electrical wires 12. The terminal portions and the core wires are connected by ultrasonic welding, resistance welding, soldering, crimping, or the like. Also, each terminal portion is embedded in the housing portion 32 by insert molding or the like, such that connection portion for connection with a conductor is embedded in the housing portion 32, and a connection portion on the other side protrudes outward. The connection portion of the terminal portion is exposed on the side of the housing main body portion 32a that is opposite to the coupling portion 32b. This connection portion is a portion used for connection to an external electrical component, and is shaped as a round terminal provided with a hole for screw fixing, a female terminal with a tubular shape, or a male terminal with a pin shape or a tab shape, for example. The sheathed electrical wires 12, which include the core wires connected to the terminal portions, extend outward from the coupling portion 32b side of the housing portion 32.

The conductive shell 34 is a member that is obtained by performing press molding on a metal plate made of stainless steel, aluminum, iron, or the like, or by performing die casting with aluminum or the like, and is shaped as a box that covers the housing main body portion 32a and the coupling portion 32b of the housing portion 32 from four surrounding sides. The conductive shell 34 has openings on the side outward of the coupling portion 32b and on the side opposite thereto.

Also, when the wiring module with electromagnetic shield 10 is incorporated into a vehicle or the like, the connector 30 is connected to various electrical components provided in the vehicle, and the sheathed electrical wires 12 are electrically connected to electrical components. At this time, the conductive shell 34 is electrically connected to a grounding portion of the vehicle, such as a metal case of an electrical component.

The tubular member 20 is a member formed with a tubular shape through which the sheathed electrical wires 12 can be routed. Here, the tubular member 20 is a conductive tube member formed from a metal such as aluminum, stainless steel, iron, or the like, or a combination of a resin with an electrically conductive resin or metal. This tubular member 20 covers the portions of the sheathed electrical wires 12 that are outside the connector 30 so as to play the role of protecting those portions and the role of electromagnetically shielding those portions.

The tubular member 20 is provided at a position separated from the connector 30 in order to enable bending of the sheathed electrical wires 12 between the tubular member 20 and the connector 30. Specifically, the tubular member 20 is a relatively hard member, and therefore also plays the role of maintaining the shape of the sheathed electrical wires 12 along a predetermined path. However, if the sheathed electrical wires 12 are in an entirely unbendable state, it is difficult to incorporate the wiring module with electromagnetic shield 10 into a vehicle or the like. In view of this, when the tubular member 20 is fixed to the vehicle, and the connector 30 is connected to an electrical component of the vehicle, by allowing easy bending therebetween, it is possible to achieve favorable workability in the incorporating operation. For this reason, a gap sufficient for allowing easy bending of the sheathed electrical wires 12 is provided between the tubular member 20 and the connector 30.

The tubular conductive braid 50 includes first conductive wires 51 that describe a helix and second conductive wires 52 that describe a helix in a direction opposite to the first conductive wires 51 about a helix axis X that is the same as a helix axis X of the first conductive wire 51, the first conductive wires 51 and the second conductive wires 52 being combined so as to form a tubular shape. More specifically, the first conductive wires 51 and the second conductive wires 52 describe helixes that wind in mutually opposite directions about the same helix axis X, and are braided so as to alternatingly be arranged above and below each other at intersections. The first conductive wires 51 and the second conductive wires 52 may be braided as single wires, or may be braided as bundles of multiple wires.

The portions of the sheathed electrical wires 12 that are between the tubular member 20 and the connector 30 are inserted into the tubular conductive braid 50. In this state, one end portion of the tubular conductive braid 50 is connected to the conductive shell 34. Here, the one end portion of the tubular conductive braid 50 is connected to the conductive shell 34 by placing the one end portion of the tubular conductive braid 50 over the portion of the outer circumference of the conductive shell 34 that covers the coupling portion 32b of the connector 30, providing a metal ring-shaped crimp member 37 around the one end portion, and then crimping the crimp member 37. Note that this connection may be performed using welding or the like.

Also, another end portion of the tubular conductive braid 50 is connected to the tubular member 20. Here, the other end portion of the tubular conductive braid 50 is connected to the tubular member 20 by placing the other end portion of the tubular conductive braid 50 over the outer circumferential portion of the end portion of the tubular member 20 on the connector 30 side, providing a metal ring-shaped crimp member 38 around the other end portion, and then causing the crimp member 38 to undergo plastic deformation so as to decrease in diameter. Note that this connection may be performed using welding or the like.

Accordingly, the sheathed electrical wires 12 are surrounded by the tubular member 20 and the tubular conductive braid 50, and the tubular member 20 and the tubular conductive braid 50 are electrically connected to the conductive shell 34, and can be grounded via the conductive shell 34. This therefore makes it possible to electromagnetically shield the sheathed electrical wires 12.

Note that a member that is insulating and can bend easily, such as a convoluted tube, may be placed around the tubular conductive braid 50.

The first conductive wires 51 and the second conductive wires 52 of the tubular conductive braid 50 describe helixes about the helix axis X. For this reason, when an induced current is generated in the first conductive wires 51 and the second conductive wires 52 by current flowing along the sheathed electrical wires 12, this induced current can flow along a circuit that describes a helix. If the first conductive wires 51 and the second conductive wires 52 are connected with low resistance at the intersections between the first conductive wires 51 and the second conductive wires 52, it can be expected that current flowing along the first conductive wires 51 or the second conductive wires 52 will flow while partially branching at the intersections. However, as the tubular conductive braid 50 degrades, oxide films or the like are formed on the surfaces of the first conductive wires 51 and the second conductive wires 52, and the resistance value increases at the intersections between the first conductive wires 51 and the second conductive wires 52. A large portion of the current generated in the first conductive wires 51 and the second conductive wires 52 therefore flows along a circuit that describes a helix. Accordingly, the first conductive wires 51 and the second conductive wires 52 have inductance, current generated in the first conductive wires 51 and the second conductive wires 52 flows with increased difficulty, and the electromagnetic shielding performance degrades.

In view of this, in the tubular conductive braid 50, the first conductive wires 51 and the second conductive wires 52 are electrically and mechanically connected at multiple locations on lines A and B that extend along the helix axis X. Here, electrically and mechanically connecting the first conductive wires 51 and the second conductive wires 52 refers to maintaining a state of being directly integrated or a state of being indirectly integrated via another member so as to obtain a state in which current can flow therebetween.

Here, intersections exist between the first conductive wires 51 and the second conductive wires 52 at multiple locations on the line A, and the first conductive wires 51 and the second conductive wires 52 are directly electrically and mechanically connected to form connection portions 54 at multiple locations (two locations in FIGS. 1 and 2) among these locations on the line A. Also, intersection locations exist between the first conductive wires 51 and the second conductive wires 52 at multiple locations on the line B, and the first conductive wires 51 and the second conductive wires 52 are directly electrically and mechanically connected to form connection portions 54 at multiple locations (two locations in FIGS. 1 and 2) among these locations on the line B.

Note that the first conductive wires 51 and the second conductive wires 52 may be directly electrically and mechanically connected only along the line A or the line B, or the first conductive wires 51 and the second conductive wires 52 may be directly electrically and mechanically connected along a larger number of lines.

FIGS. 3 to 5 are illustrative diagrams showing an example of an operation of connecting the first conductive wires 51 and the second conductive wires 52.

First, as shown in FIG. 3, a tubular conductive braid 50B, in which the first conductive wires 51 and the second conductive wires 52 are not connected, is prepared.

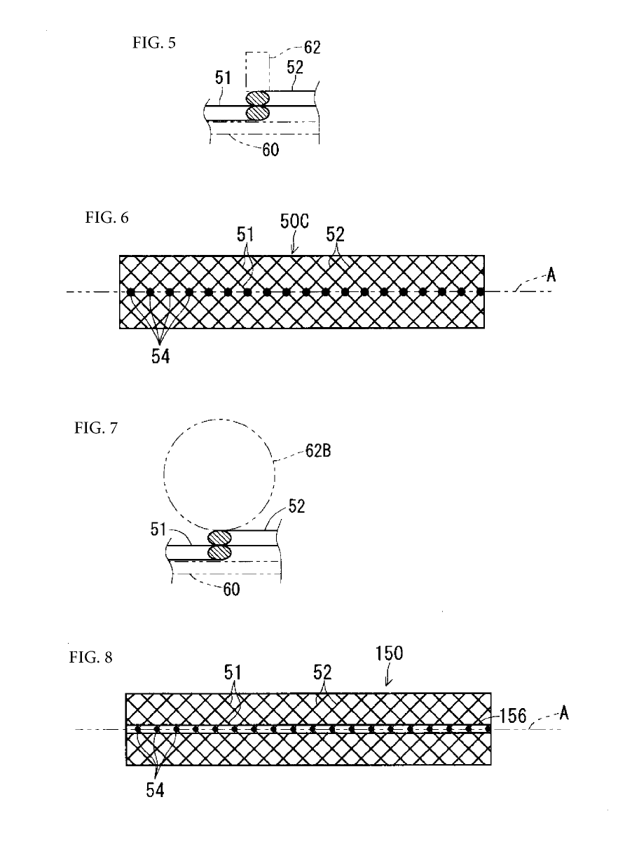

Then, as shown in FIGS. 4 and 5, an elongated welding head 60 is inserted into the tubular conductive braid 50B and arranged on the inner circumferential side of the line A (or line B) of the tubular conductive braid 50B. A pin-shaped welding head 62 is then arranged at an intersection between a first conductive wire 51 and a second conductive wire 52 on the outer circumferential side of the line A (or line B) of the tubular conductive braid 50B. The intersection between the first conductive wire 51 and the second conductive wire 52 is then sandwiched between the welding head 60 and the welding head 62 on the inside and the outside of the tubular conductive braid 50B. When current flows between the welding head 60 and the welding head 62 in this state, the first conductive wire 51 and the second conductive wire 52 melt due to Joule heat and become resistance welded at the intersection.

The welding head 62 is then moved along the line A (or the line B), and another intersection between a first conductive wire 51 and a second conductive wire 52 is similarly resistance welded.

Accordingly, the first conductive wires 51 and the second conductive wires 52 are electrically and mechanically joined at multiple locations along the line A (or the line B), thus maintaining a state of being directly integrated.

Although an example of resistance welding the first conductive wires 51 and the second conductive wires 52 is described above, the first conductive wires 51 and the second conductive wires 52 may be welded by ultrasonic welding, heat welding, or the like, or may be joined by soldering or the like.

According to the tubular conductive braid 50 that is configured as described above, the first conductive wires 51 and the second conductive wires 52 are electrically and mechanically connected at multiple locations on the lines A and B that extend along the helix axis X, and therefore current flowing along the first conductive wires 51 is branched to the second conductive wires 52 at a midpoint. Similarly, current flowing along the second conductive wires 52 is also branched to the first conductive wires 51 at a midpoint. In particular, because the first conductive wires 51 and the second conductive wires 52 are mechanically connected, the state of the electrical connection between the first conductive wires 51 and the second conductive wires 52 is also maintained in a favorable state. For this reason, current flowing along the first conductive wires 51 and the second conductive wires 52 is not likely to rotate many times around the helix axis X, thus making it possible to prevent, as much as possible, the tubular conductive braid 50 from having inductance. Accordingly, current flowing along the first conductive wires 51 and the second conductive wires 52 can easily flow along the tubular conductive braid 50.

For this reason, in the case where the tubular conductive braid 50 is used as an electromagnetic shield for the sheathed electrical wires 12 for example, current generated in the first conductive wires 51 and the second conductive wires 52 by electromagnetic induction can be allowed to escape to the conductive shell 34 or the like with low resistance, thus making it possible to favorably maintain the shielding performance. Also, because the shielding performance can be made favorable, the size of the tubular conductive braid 50 can be reduced, and it is possible to contribute to a reduction in weight as well.

In the first place, it is not essential that the tubular conductive braid 50 is used as an electromagnetic shield, and it may be used as a power line or a signal line.

Also, the first conductive wires 51 and the second conductive wires 52 are electrically and mechanically connected by being welded or the like at intersections therebetween, and therefore it is possible to easily realize an electrical and mechanical connection between the first conductive wires 51 and the second conductive wires 52.

Also, the first conductive wires 51 and the second conductive wires 52 are electrically and mechanically connected at multiple locations on the lines A and B, and therefore current flowing along the first conductive wires 51 and the second conductive wires 52 is not likely to rotate many times around the helix axis X, and as a result, it is possible to further reduce the inductance of the tubular conductive braid 50.

Note that in the above embodiment, an example is described in which the first conductive wires 51 and the second conductive wires 52 are electrically and mechanically connected at a portion of the intersections between the first conductive wires 51 and the second conductive wires 52 along the line A, but a configuration is possible in which, as with a tubular conductive braid 50C of a first variation shown in FIG. 6, the first conductive wires 51 and the second conductive wires 52 are electrically and mechanically connected in a consecutive manner at intersections between the first conductive wires 51 and the second conductive wires 52 along the line A (i.e., there are no intersections at midpoints where the first conductive wires 51 and the second conductive wires 52 are not connected). In the first variation, the first conductive wires 51 and the second conductive wires 52 are electrically and mechanically connected in a consecutive manner at all intersections between the first conductive wires 51 and the second conductive wires 52 along the line A.

Note that at the end portions of the tubular conductive braid 50C, the first conductive wires 51 and the second conductive wires 52 are not connected, and in the intermediate portion of the tubular conductive braid 50C, the first conductive wires 51 and the second conductive wires 52 are electrically and mechanically connected in a consecutive manner.

Note that the consecutive welding of the first conductive wires 51 and the second conductive wires 52 described above can be easily performed by, for example, using a disc-shaped welding head 62B shown in FIG. 7 instead of the welding head 62, and rolling the welding head 62B over the tubular conductive braid 50B on the welding head 60.

In this way, if the first conductive wires 51 and the second conductive wires 52 are electrically and mechanically connected in a consecutive manner at multiple intersections between the first conductive wires 51 and the second conductive wires 52 along the line A, current flowing along the first conductive wires 51 and the second conductive wires 52 is not likely to rotate many times around the helix axis X, and as a result, it is possible to further reduce the inductance of the tubular conductive braid 50C.

### Second Embodiment

A tubular conductive braid 150 according to a second embodiment will be described below. FIG. 8 is a schematic side view of the tubular conductive braid 150 according to the second embodiment. Note that in the description of the present embodiment, constituent elements similar to those described in the first embodiment will be denoted by the same reference signs, and descriptions will not be given for them.

Similarly to the tubular conductive braid 50 of the first embodiment, the tubular conductive braid 150 includes first conductive wires 51 and second conductive wires 52 that are combined so as to form a tubular shape, and is applicable as an electromagnetic shield in the wiring module with electromagnetic shield 10 for example.

A main difference that the tubular conductive braid 150 has from the tubular conductive braid 50 is that a linear conductor 156 is provided separately.

Specifically, in this tubular conductive braid 150, the first conductive wires 51 and the second conductive wires 52 are electrically and mechanically connected in a consecutive manner to form connection portions 54 at multiple intersections between the first conductive wires 51 and the second conductive wires 52 on the line A.

Also, the linear conductor 156 is arranged extending along the line A, and the consecutive connection portions 54 between the first conductive wires 51 and the second conductive wires 52 are electrically and mechanically connected to the linear conductor 156 as well. Here, electrically and mechanically connecting the connection portion 54 and the linear conductor 156 refers to maintaining a state of being directly integrated or a state of being indirectly integrated via another member so as to obtain a state in which current can flow therebetween. Note that a configuration is possible in which linear conductors are arranged extending along multiple lines, and are electrically and mechanically connected to the connection portions.

A strip-shaped member made of a metal foil such as copper foil, a metal wire such as a copper wire, or the like can be used as the linear conductor 156. The linear conductor 156 is arranged so as to come into contact with the inner circumference or the outer circumference of the tubular conductive braid 150 along the line A. Here, the linear conductor 156 is arranged on the outer circumferential side of the tubular conductive braid 150. Also, the connection portions 54 are electrically and mechanically connected to the linear conductor at locations of contact with the linear conductor 156.

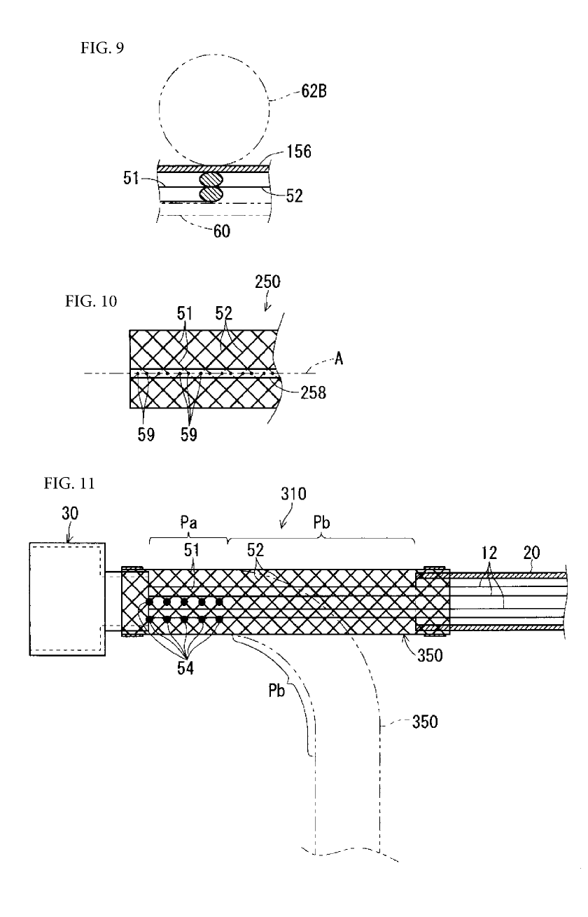

The above-described connection operation can be performed as shown in FIG. 9, for example.

Specifically, the elongated welding head 60 is inserted into the tubular conductive braid 50B and arranged on the inner circumferential side of the line A of the tubular conductive braid 50B. Also, the linear conductor 156 is arranged on the outer circumferential side of the tubular conductive braid 50B along the line A. The linear conductor 156 is arranged on the outer side of intersections between the first conductive wires 51 and the second conductive wires 52 on the line A.

In this state, the disc-shaped welding head 62B is rolled over the outer surface of the linear conductor 156. Accordingly, the first conductive wires 51, the second conductive wires 52, and the linear conductor 156 are sandwiched between the welding head 60 and the welding head 62B at consecutive intersections between the first conductive wires 51 and the second conductive wires 52 on the line A, thus being resistance welded between the welding head 60 and the welding head 62B.

Accordingly, the first conductive wires 51, the second conductive wires 52, and the linear conductor 156 are electrically and mechanically joined at intersections between the first conductive wires 51 and the second conductive wires 52 along the line A.

Of course, the first conductive wires 51, the second conductive wires 52, and the linear conductor 156 may be welded by ultrasonic welding, heat welding, or the like, or may be joined by soldering or the like.

According to the second embodiment, in addition to the effects of the first embodiment, current flowing along the first conductive wires 51 and the second conductive wires 52 also flows along the linear conductor 156 that extends along the line A, thereby flowing without describing a helix. For this reason, it is possible to reduce the inductance of the tubular conductive braid 150.

### Third Embodiment

A tubular conductive braid 250 according to a third embodiment will be described below. FIG. 10 is a schematic partial side view of the tubular conductive braid 250 according to the third embodiment. Note that note that in the description of the present embodiment, constituent elements similar to those described in the first embodiment will be denoted by the same reference signs, and descriptions will not be given for them.

Similarly to the tubular conductive braid 50 of the first embodiment, the tubular conductive braid 250 includes first conductive wires 51 and second conductive wires 52 that are combined so as to form a tubular shape, and is applicable as an electromagnetic shield in the wiring module with electromagnetic shield 10 for example.

A main difference that the tubular conductive braid 250 has from the tubular conductive braid 50 is the configuration of the electrical and mechanical connection of the first conductive wires 51 and the second conductive wires 52.

Specifically, in the present embodiment, the first conductive wires 51 and the second conductive wires 52 are electrically and mechanically connected via a linear conductor 258 that is arranged extending along the line A.

More specifically, in this tubular conductive braid 250, the linear conductor 258 is arranged extending along the line A. The line A is set so as to pass through positions that avoid intersections between the first conductive wires 51 and the second conductive wires 52, and therefore the linear conductor 258 intersects the first conductive wires 51 and the second conductive wires 52, but does not pass through intersections between the first conductive wires 51 and the second conductive wires 52.

A strip-shaped member made of a metal foil such as copper foil, a metal wire such as a copper wire, or the like can be used as the linear conductor 258. The linear conductor 258 is arranged so as to come into contact with the inner circumference or the outer circumference of the tubular conductive braid 150 along the line A. Here, the linear conductor 258 is arranged on the outer circumferential side of the tubular conductive braid 150.

The first conductive wires 51 and the second conductive wires 52 are then joined to the linear conductor 258 by welding, soldering, or the like at intersections with the linear conductor 258, thus forming joined portions 59. Accordingly, the first conductive wires 51 and the second conductive wires 52 are electrically connected via the linear conductor 258, and a state of being indirectly integrated is maintained so as to maintain this state of being electrically connected via the linear conductor.

The above-described connection operation can be performed similarly to the description given with reference to FIG. 9, for example.

According to the third embodiment, current flowing along the first conductive wires 51 and the second conductive wires 52 also flows along the linear conductor 258 that extends along the line A, thereby flowing without describing a helix. For this reason, it is possible to reduce the inductance of the tubular conductive braid 250.

Variations

FIG. 11 shows a second variation that is premised on the first embodiment and is a variation regarding the formation positions of the connection portions 54 in the case where a wiring module with electromagnetic shield 310, which includes a tubular conductive braid 350 that corresponds to the tubular conductive braid 50, is arranged along a predetermined path.

Here, the tubular conductive braid 350 is arranged along a path that includes a curved path Pb and a straight path Pa. In this case, it is preferable that the first conductive wires 51 and the second conductive wires 52 are electrically and mechanically connected to form the connection portions 54 in a portion of the tubular conductive braid 350 that is arranged along the straight path Pa, in a direction along the helix axis X.

This is because when the first conductive wires 51 and the second conductive wires 52 are electrically and mechanically connected to form the connection portions 54, the tubular conductive braid 350 bends less readily in that portion. Accordingly, the tubular conductive braid 350 would be likely to maintain a straight state in the path Pb.

On the other hand, the portion of the tubular conductive braid 350 in which the connection portions 54 are not formed is likely to bend relatively easily. For this reason, it is preferable that the first conductive wires 51 and the second conductive wires 52 are electrically and mechanically connected to form the connection portions 54 in a portion of the tubular conductive braid 350 that that excludes a portion that is arranged along a bent path, that is to say excludes a portion arranged along the path Pb, in a direction along the helix axis X.

Accordingly, the tubular conductive braid 350 can be arranged while easily bending along the path Pb.

Note that the configurations described in the above embodiments and variations can be appropriately combined as long as no contradiction arises. For example, the formation positions of the connection portions 54 described in the second variation can also be applied to the connection portions 54 in the second embodiment and the connection locations that include the joined portions 59 in the third embodiment.

Although this invention has been described in detail above, the above description is illustrative in all respects, and this invention is not limited to the above description. It will be understood that numerous variations not illustrated here can be envisioned without departing from the range of this invention.

1. A tubular conductive braid comprising:
first conductive wires that describe a helix and second conductive wires that describe a helix in a direction opposite to the first conductive wires about a helix axis that is the same as a helix axis of the first conductive wires, the first conductive wires and the second conductive wires being combined so as to form a tubular shape,
wherein the first conductive wires and the second conductive wires are electrically and mechanically connected at a plurality of locations on a line that extends along the helix axis.

2. The tubular conductive braid according to claim 1, wherein the first conductive wires and the second conductive wires are electrically and mechanically connected at intersections therebetween.

3. The tubular conductive braid according to claim 2, wherein a linear conductor is arranged along the line, and an electrical and mechanical connection portion of the first conductive wires and the second conductive wires is electrically and mechanically connected to the linear conductor.

4. The tubular conductive braid according to claim 1, wherein the first conductive wires and the second conductive wires are electrically and mechanically connected by soldering or welding.

5. The tubular conductive braid according to claim 1, wherein the first conductive wires and the second conductive wires are electrically and mechanically connected via a linear conductor that is arranged extending along the line.

6. The tubular conductive braid according to claim 5, wherein the first conductive wires and the second conductive wires are electrically and mechanically connected via the linear conductor by being soldered or welded to the linear conductor.

7. The tubular conductive braid according to claim 1, wherein the first conductive wires and the second conductive wires are electrically and mechanically connected in a portion arranged along a straight path, in a direction along the helix axis.

8. The tubular conductive braid according to claim 1, wherein the first conductive wires and the second conductive wires are electrically and mechanically connected in a portion excluding a portion arranged along a curved path, in a direction along the helix axis.

9. A wiring module with electromagnetic shield comprising:
a wiring member; and
the tubular conductive braid according to claim 1, the tubular conductive braid surrounding the wiring member as an electromagnetic shield.
